(19) United States
(12) Patent Application Publication
(10) Pub. No.: US 2016/0071863 A1
(43) Pub. Date: Mar. 10, 2016

(54) METHOD OF MANUFACTURING SEMICONDUCTOR STORAGE APPARATUS, AND SEMICONDUCTOR STORAGE APPARATUS

(71) Applicant: KABUSHIKI KAISHA TOSHIBA, Minato-ku (JP)

(72) Inventors: Akio KANEKO, Yokkaichi (JP); Wataru SAKAMOTO, Yokkaichi (JP); Takeshi MURATA, Yokkaichi (JP)

(73) Assignee: KABUSHIKI KAISHA TOSHIBA, Minato-ku (JP)

(21) Appl. No.: 14/638,615

(22) Filed: Mar. 4, 2015

Related U.S. Application Data
(60) Provisional application No. 62/048,464, filed on Sep. 10, 2014.

(51) Int. Cl. H01L 27/115; H01L 21/265; H01L 21/324; H01L 21/3115; H01L 21/02

(52) U.S. Cl. CPC H01L 27/11568; H01L 21/31155; H01L 21/0217; H01L 21/02164; H01L 21/02126; H01L 21/324; H01L 21/26513; H01L 27/11573; H01L 27/11521; H01L 27/11531

(57) ABSTRACT

A method of manufacturing a semiconductor storage apparatus according to an embodiment includes forming an array of a plurality of memory cells. The method includes forming an interlayer insulating film that covers the memory cells. The method includes forming a first nitride film that covers an upper part of the interlayer insulating film. The method includes ion-implanting a first impurity into the first nitride film.

### CROSS-REFERENCE TO RELATED APPLICATION

This application is based upon and claims the benefit of U.S. provisional Application No. 62/048,464, filed on Sep. 10, 2014, the entire contents of which are incorporated herein by reference.

### BACKGROUND

1. Field

Embodiments described herein relate generally to a method of manufacturing a semiconductor storage apparatus, and a semiconductor storage apparatus.

2. Background Art

A NAND flash memory is a conventional semiconductor storage apparatus. The semiconductor storage apparatus includes a memory cell transistor having a tunnel insulating film.

During an annealing treatment in a process of manufacturing such a semiconductor storage apparatus, the tunnel insulating film or the like of the memory cell transistor can react with hydrogen in an oxide film, such as an interlayer film, and deteriorate. The deterioration of the tunnel oxide film leads to a decrease of the reliability of the memory cell transistor, for example.

### BRIEF DESCRIPTION OF THE DRAWINGS

FIG. 1 is a circuit diagram showing an example of an equivalent circuit of a part of a memory cell array formed in a memory cell region of a NAND flash memory 1;

FIG. 2 is a plan view of a layout pattern of a part of the memory cell region shown in FIG. 1;

FIG. 3 is a cross-sectional view schematically showing a cross-sectional structure of the NAND flash memory;

FIG. 4 is a cross-sectional view showing an example of a step of the method of manufacturing the semiconductor storage apparatus according to this embodiment;

FIG. 5 is a cross-sectional view showing an example of a step of the method of manufacturing the semiconductor storage apparatus according to this embodiment, and continuous from FIG. 4;

FIG. 6 is a cross-sectional view showing an example of a step of the method of manufacturing the semiconductor storage apparatus according to this embodiment, and continuous from FIG. 5;

FIG. 7 is a cross-sectional view showing an example of a step of the method of manufacturing the semiconductor storage apparatus according to this embodiment, and continuous from FIG. 6;

FIG. 8 is a cross-sectional view showing an example of a step of the method of manufacturing the semiconductor storage apparatus according to this embodiment, and continuous from FIG.7;

FIG. 9 is a cross-sectional view showing an example of a step of the method of manufacturing the semiconductor storage apparatus according to this embodiment, and continuous from FIG. 8;

FIG. 10 is a cross-sectional view showing an example of a step of the method of manufacturing the semiconductor storage apparatus according to this embodiment, and continuous from FIG. 9;

FIG. 11 is a cross-sectional view showing an example of a step of the method of manufacturing the semiconductor storage apparatus according to this embodiment, and continuous from FIG. 10;

FIG. 12 is a cross-sectional view showing an example of a step of the method of manufacturing the semiconductor storage apparatus according to this embodiment, and continuous from FIG. 11;

FIG. 13 is a cross-sectional view showing an example of a step of the method of manufacturing the semiconductor storage apparatus according to this embodiment, and continuous from FIG. 12;

FIG. 14 is a cross-sectional view showing an example of a step of the method of manufacturing the semiconductor storage apparatus according to this embodiment, and continuous from FIG. 13;

FIG. 15 is a cross-sectional view showing an example of a step of the method of manufacturing the semiconductor storage apparatus according to this embodiment, and continuous from FIG. 14; and

FIG. 16 is a characteristic diagram showing an example of relationships between a voltage change ΔVge of the voltage that is applied to the tunnel oxide film when a constant current is passed through the tunnel oxide film for a prescribed time and various kinds of impurities ion-implanted.

### DETAILED DESCRIPTION

A method of manufacturing a semiconductor storage apparatus according to an embodiment includes forming an array of a plurality of memory cells. The method includes forming an interlayer insulating film that covers the memory cells. The method includes forming a first nitride film that covers an upper part of the interlayer insulating film. The method includes ion-implanting a first impurity into the first nitride film.

### DETAILED DESCRIPTION OF THE INVENTION

In the following, an embodiment will be described with reference to the drawings. In the embodiment, substantially the same components are denoted by the same reference numerals, and redundant descriptions thereof will be omitted. The drawings are schematic drawings, and the ratios between thickness and planar dimensions and between thicknesses of layers differ from the actual ratios.

### First Embodiment

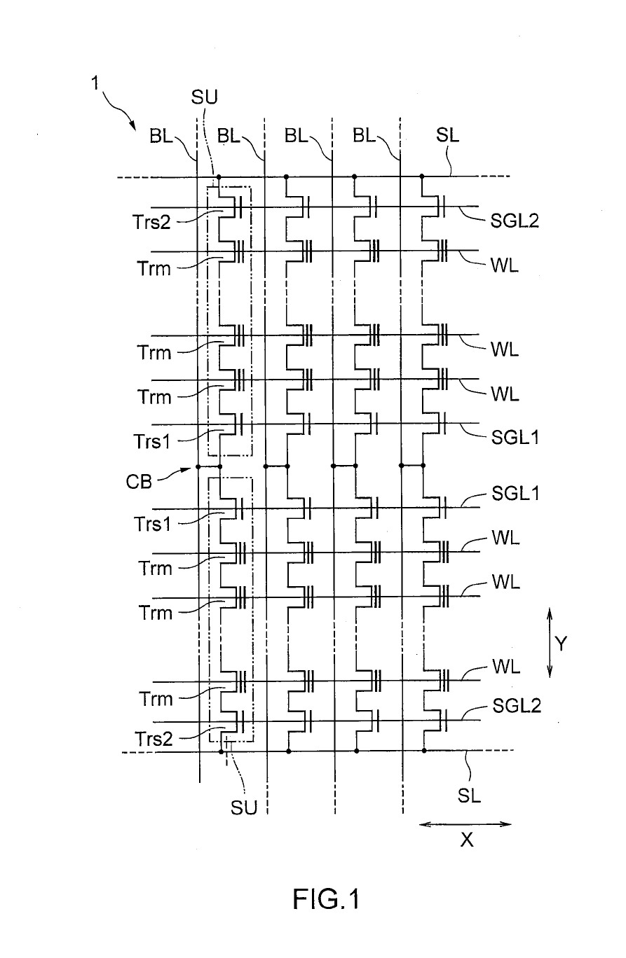

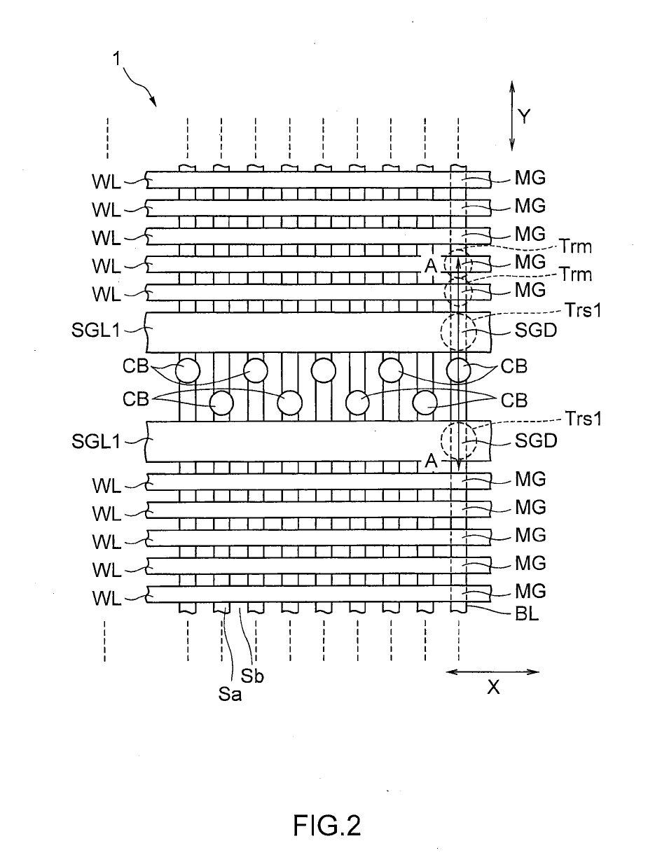

First, an example of a structure of a NAND flash memory, which is a semiconductor storage apparatus according to a first embodiment, will be described. FIG. 1 is a circuit diagram showing an example of an equivalent circuit of a part of a memory cell array formed in a memory cell region of a NAND flash memory 1. FIG. 2 is a plan view of a layout pattern of a part of the memory cell region shown in FIG. 1.

As shown in FIG. 1, the NAND flash memory 1 has a memory cell array including a matrix of NAND cell units “SU”, the NAND cell unit “SU” including two selecting gate transistors “Trs1” and “Trs2” and a plurality of (64, for example) memory cell transistors (memory cells) “Trm” connected in series with each other between the selecting gate transistors “Trs1” and “Trs2”. In the NAND cell unit “SU”, each of the plurality of memory cell transistors “Trm” shares a source region and a drain region with an adjacent memory cell transistor “Trm”.

The memory cell transistors “Trm” disposed side by side in an X direction (which corresponds to the direction of a word line) in FIG. 1 are connected to a common word line “WL”. The selecting gate transistors “Trs1” disposed side by side in the X direction in FIG. 1 are connected to a common selecting gate line “SGL1”, the selecting gate transistors “Trs2” disposed side by side in the X direction are connected to a common selecting gate line “SGL2”.

A bit line contact “CB” is connected to the drain region of the selecting gate transistor “Trs1”. The bit line contact “CB” is connected to a bit line “BL” that extends in a Y direction (which corresponds to the longitudinal direction of the gate) that is perpendicular to the X direction in FIG. 1. The selecting gate transistor “Trs2” is connected to a source line “SL” that extends in the X direction in FIG. 1 through the source region.

As shown in FIG. 2, a plurality of device isolation regions “Sb” (a shallow trench isolation (STI), for example) that extend in the Y direction in FIG. 2 are formed. The plurality of device isolation regions “Sb” are formed at predetermined intervals in the X direction in FIG. 2. As a result, a plurality of active regions “Sa” are formed which extend in the Y direction in FIG. 2 and are spaced apart from each other in the X direction.

The word line “WL” is formed to extend in the direction (X direction in FIG. 2) perpendicular to the active regions “Sa”. A plurality of word lines “WL” are arranged at predetermined intervals in the Y direction in FIG. 2. A multilayer gate electrode “MG” of the memory cell transistor “Trm” is formed on the active region “Sa” that intersects with the word line “WL”.

A bit line contact region is formed between the selecting gate transistors “Trs1” of the NAND cell units “SU” that are adjacent to each other in the Y direction. The bit line contact “CB” is formed in the bit line contact region. One bit line contact “CB” is formed in each of the active regions “Sa” between the adjacent selecting gate transistors “Trs1” (see FIG. 2).

A peripheral transistor (not shown) is provided in a peripheral circuit region (not shown) around the memory cell array shown in FIGS. 1 and 2.

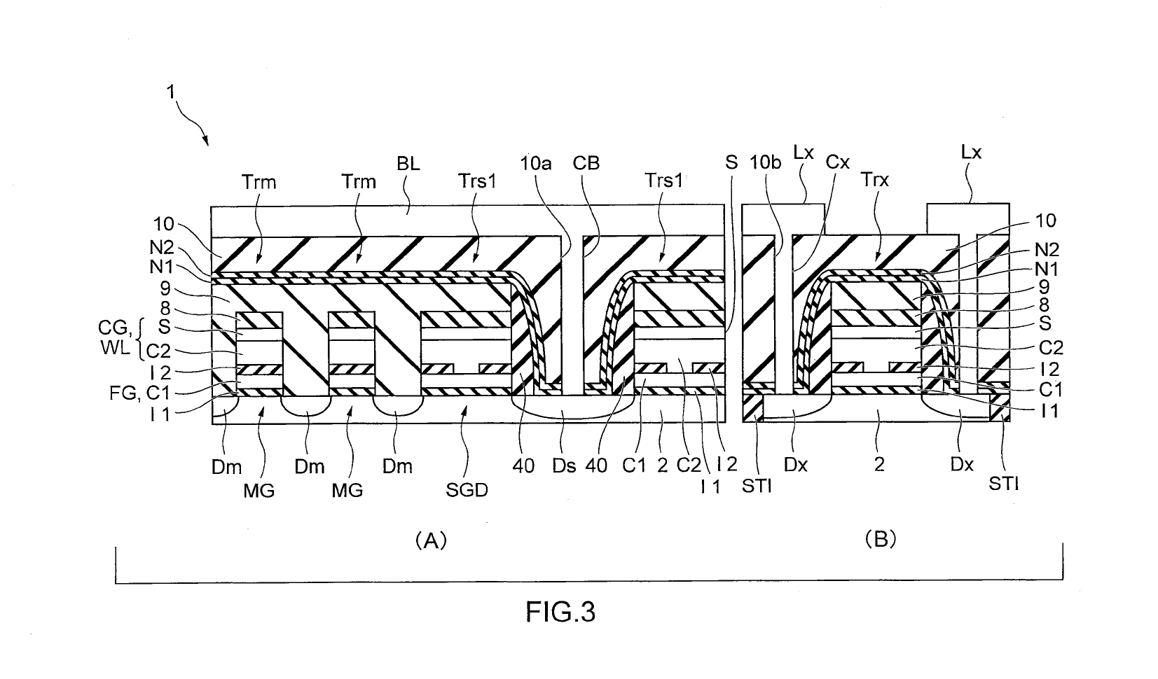

FIG. 3 is a cross-sectional view schematically showing a cross-sectional structure of the NAND flash memory. In particular, region (A) shows a cross-sectional structure of the memory cell region of the NAND flash memory 1 shown in FIG. 2 taken along the line A-A in FIG. 2. Region (B) shows a cross-sectional structure of a peripheral transistor in a peripheral circuit region provided around the memory cell region. Further, region (A) schematically shows a cross-sectional structure of a periphery of the bit line contact “CB” between a pair of selecting gate transistors “Trs1”. Illustration of a peripheral transistor “Trx” shown in region (B) is omitted in FIGS. 2 and 3.

As shown in FIG. 3, the NAND flash memory 1 includes a semiconductor substrate 2, the memory cell transistors “Trm”, the selecting gate transistors “Trs1”, the peripheral transistor “Trx”, a first nitride film “N1”, a second nitride film “N2”, interlayer insulating films 9 and 10, the bit line contacts “CB”, the bit lines “BL”, contacts “Cx”, and wires “Lx”, for example. As described above, the NAND flash memory 1 also includes components other than those shown in FIG. 3. The second nitride film “N2” may be omitted.

As shown in FIG. 3, a gate insulating film (tunnel insulating film) “I1” is formed on the semiconductor substrate 2. The gate insulating film “I1” is a silicon oxide film, for example, and is formed over an upper surface of the semiconductor substrate 2 in regions where the memory cell transistors “Trm”, the selecting gate transistors “Trs1” and the peripheral transistor “Trx” are formed. However, the gate insulating film “I1” is not formed on the semiconductor substrate 2 in regions in vicinities of the sides of the bit line contacts “CB”. The gate insulating film “I1” is actually the tunnel insulating film of the memory cell transistor “Trm” (and will sometimes be referred to as a tunnel insulating film in the description of the memory cell transistor “Trm” below).

As shown in region (A) of FIG. 3, the memory cell transistor “Trm” has a cell structure including the gate insulating film (tunnel insulating film) “I1” formed on the semiconductor substrate 2, the multilayer gate electrode “MG” formed on the tunnel insulating film “I1” and a diffusion layer “Dm” that is formed in the semiconductor substrate 2 and forms a source region and a drain region (referred to as a source/drain region, hereinafter) disposed at the opposite sides of the multilayer gate electrode “MG”.

The multilayer gate electrode (multilayer structure) “MG” includes a charge storing layer formed on the gate insulating film (tunnel insulating film) “I1”, such as a floating gate electrode “FG” formed by a silicon layer “C1”, an inter-gate insulating film (an intermediate insulating film) “I2” formed on the floating gate electrode “FG”, and a control gate electrode (silicon layer “C2”, silicide layer “S”) “CG” formed on the inter-gate insulating film “I2”.

The source/drain region “Dm” is formed in the surface layer of the silicon substrate 2 at the sides of the floating gate electrode “FG”.

The inter-gate insulating film “I2” is an insulating film disposed between the floating gate electrode “FG” and the control gate electrode “CG”.

The control gate electrode “CG” includes the silicon layer “C2” and the silicide layer “S” formed on the silicon layer “C2”. The control gate electrode “CG” is connected to the word line “WL”.

The silicide layer “S” is a layer of a silicide of tungsten or other low-resistance metal formed in an upper part of the silicon layer “C2”. A silicon nitride film 8 is formed on the silicide layer “S”.

As shown in region (A) of FIG. 3, the interlayer insulating film 9 is formed on the multilayer gate electrode “MG”, the selecting gate electrode “SGD” and the source/drain region “Dm” (the interlayer insulating film 9 covers the memory cell).

The interlayer insulating film 9 may be a tetraethyl orthosilicate (TEOS) film, such as a densified tetraethyl orthosilicate (DTEOS) film or a low-pressure tetraethyl orthosilicate (LPTEOS) film, or a boro-phospho silicate glass (BPSG) film, for example.

The first and second nitride films “N1” and “N2” are formed on the interlayer insulating film 9. The first and second nitride films “N1” and “N2” have barrier characteristics that barrier unwanted matters (such as carbon and hydrogen) in film formation and function as barrier insulating films.

The first nitride film “N1” is disposed on a gate side wall 40, source/drain regions “Ds” and “Dx” and the interlayer insulating film 9. The first nitride film “N1” is a silicon nitride film, for example.

The first nitride film “N1” contains any of BF₂, As or P as a first impurity. More preferably, the first impurity exists in a region of the interlayer insulating film 9 directly below the first nitride film “N1” (between the upper part of the multilayer gate electrode “MG” and the lower part of the first nitride film “N1”). In particular, a peak of the concentration distribution of the first impurity lies in the region of the interlayer insulating film 9 directly below the first nitride film “N1”.

As a result, as described later, in manufacture of the NAND flash memory (in a heat treatment such as activation annealing), the tunnel insulating film “I1” of the memory cell transistor “Trm” can be prevented from reacting with hydrogen of an ethyl or the like in the interlayer insulating films 9 and 10. In other words, deterioration of the tunnel insulating film “I1” of the memory cell transistor “Trm” can be prevented.

The second nitride film “N2” is formed on the first nitride film “N1”. The second nitride film “N2” is a silicon nitride film, for example. As described above, the second nitride film “N2” may be omitted.

The interlayer insulating film 10 is formed on the second nitride film “N2” on the first nitride film “N1”.

As shown in region (A) of FIG. 3, the selecting gate transistor “Trs1” is formed adjacent to the memory cell transistor “Trm”.

The selecting gate electrode “SGD” of the selecting gate transistor “Trs1” has basically the same structure as the multilayer gate electrode “MG” of the memory cell transistor “Trm”. The selecting gate electrode “SGD” of the selecting gate transistor “Trs1” has a structure including a stack of the silicon layer “C1”, the inter-gate insulating film “I2”, the silicon layer “C2” and the silicide layer “S”. However, a through-hole is formed substantially at the center of the inter-gate insulating film “I2” so that the silicon layers “C1” and “C2” are structurally in contact with each other, thereby making the inter-gate insulating film “I2” in the gate electrode ineffective.

The selecting gate electrode of the selecting gate transistor “Trs2” shown in FIGS. 1 and 2 has the same structure as the selecting gate electrode “SGD”.

As shown in region (A) of FIG. 3, the bit line contact “CB” is formed in a contact hole 10a that penetrates the interlayer insulating film 10 and the first and second nitride films “N1” and “N2”.

The bit line “BL” is formed on the interlayer insulating film 10 and is connected to the bit line contact “CB”.

As shown in region (A) of FIG. 3, in the peripheral circuit region adjacent to the memory cell region of the NAND flash memory 1, the peripheral transistor “Trx” is provided.

The gate electrode of the peripheral transistor “Trx” has substantially the same structure as the selecting gate electrode of the selecting transistor “Trs1”.

The contact “Cx” is connected to the source/drain region “Dx” of the peripheral transistor “Trx”. The contact “Cx” is formed in a contact hole 10b that penetrates the interlayer insulating film 10 and the first and second nitride films “N1” and “N2”.

The wire “Lx” is provided on the interlayer insulating film 10 and is connected to the contact “Cx”.

Next, an example of a method of manufacturing the NAND flash memory 1 that is a semiconductor storage apparatus configured as described above will be described. Although the description of this embodiment is focused on characteristic parts thereof, any common step can be additionally provided between steps, or any step can be omitted as required. The order of steps can be changed as required if such a change is feasible.

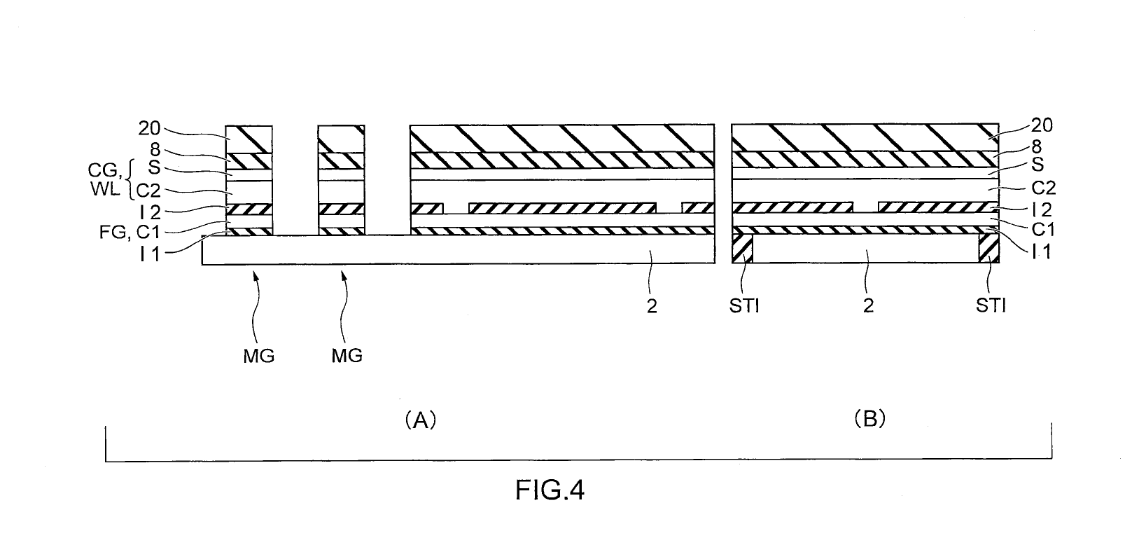

FIGS. 4 to 15 are cross-sectional views each showing an example of a step of the method of manufacturing the semiconductor storage apparatus according to this embodiment. Region (A) of FIGS. 4 to 15 schematically shows vertical cross-sectional structures of the memory cell transistor and selecting transistor shown in region (A) of FIG. 3 at different manufacturing stages. Region (B) of FIGS. 4 to 15 schematically show vertical cross-sectional structures of the peripheral transistor shown in region (B) of FIG. 3 at different manufacturing stages.

As shown in FIG. 4, first, the gate insulating film (tunnel insulating film) “I1” is formed on the semiconductor substrate 2 by thermal oxidation, for example. On the gate insulating film “I1”, the silicon layer “C1” that is to form the floating gate electrode “FG” is then deposited by chemical vapor deposition (CVD), for example. On the silicon layer “C1”, the inter-gate insulating film “I2”, such as an ONO film, is formed by CVD, for example. On the inter-gate insulating film “I2”, the silicon layer “CS” is formed by CVD, for example. On the upper surface of the silicon layer “C2”, a film of tungsten (W) or the like is then formed by sputtering, and a heat treatment, such as reactive ion etching (RIE), is performed on the film to form the silicide layer “S”. On the silicide layer “S”, the silicon nitride film 8 serving as a cap film is formed by CVD, for example.

After that, a hard mask 20 is formed by patterning on the silicon nitride film 8, and then, the silicon nitride film 8 is etched by anisotropic etching using the hard mask 20 as a mask. Anisotropic etching is then performed on the silicon layer “C2”, the inter-gate insulating film “I2”, the silicon layer “C1” and the gate insulating film “I1”. In this way, the multilayer gate electrode “MG” of the memory cell transistor “Trm” is formed on the tunnel insulating film “I1” (region (A) of FIG. 4).

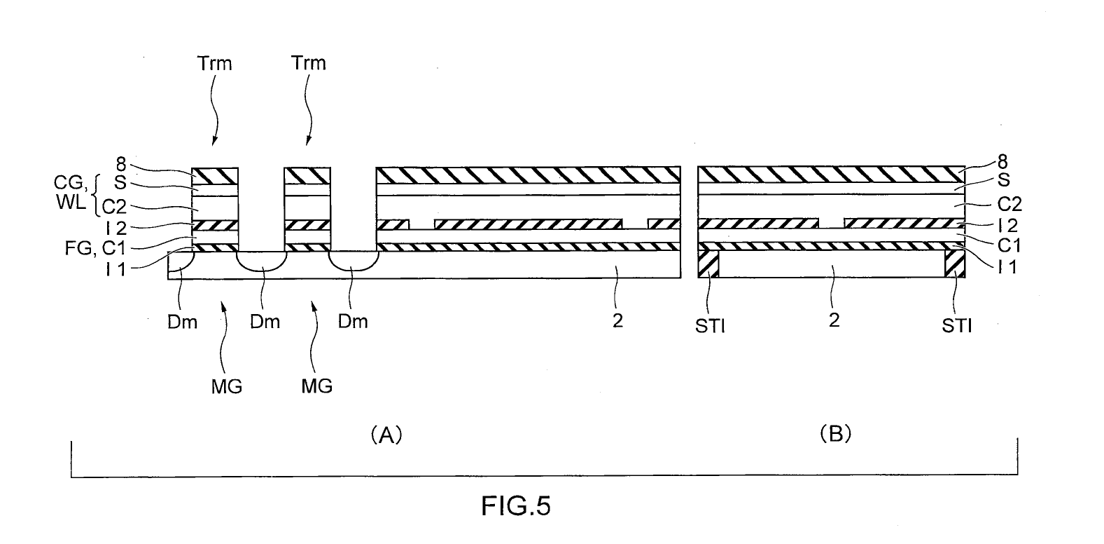

As shown in FIG. 5, a first impurity is implanted into a surface layer of the semiconductor substrate 2 by ion implantation using the multilayer gate electrode “MG” as a mask. A heat treatment required to activate the first impurity is then performed to form a diffusion layer as the source/drain region “Dm” in a self-aligned manner.

In this way, the source/drain regions “Dm” of the memory cell transistor “Trm” disposed at the opposite sides of the multilayer gate electrode “MG” are formed on the semiconductor substrate 2 (region (A) of FIG. 5).

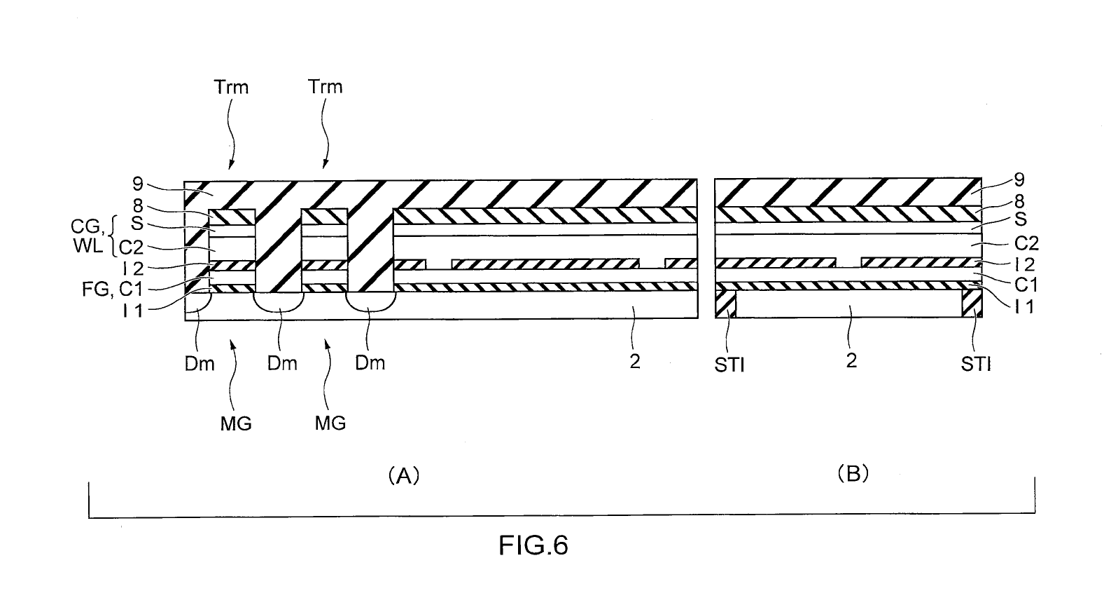

As shown in FIG. 6, the interlayer insulating film 9 is then formed by CVD, for example, so as to cover the silicon nitride film 8, the multilayer gate electrode “MG” and the source/drain regions “Dm”.

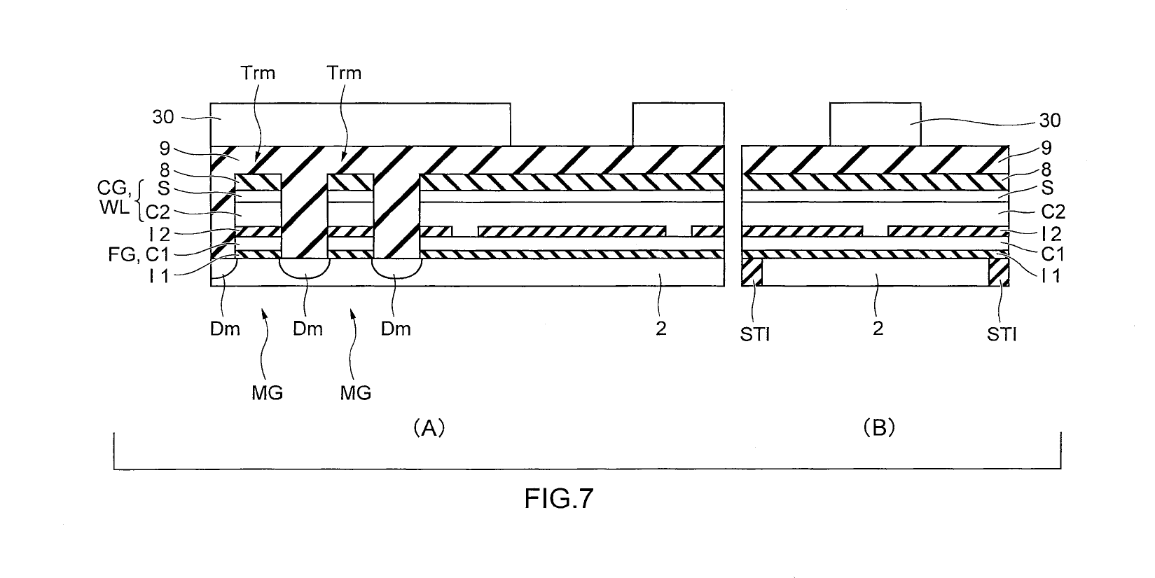

As shown in FIG. 7, a resist pattern 30 used to form the gate electrodes of the selecting gate transistor “Trs1” and the peripheral transistor “Trx” is then formed.

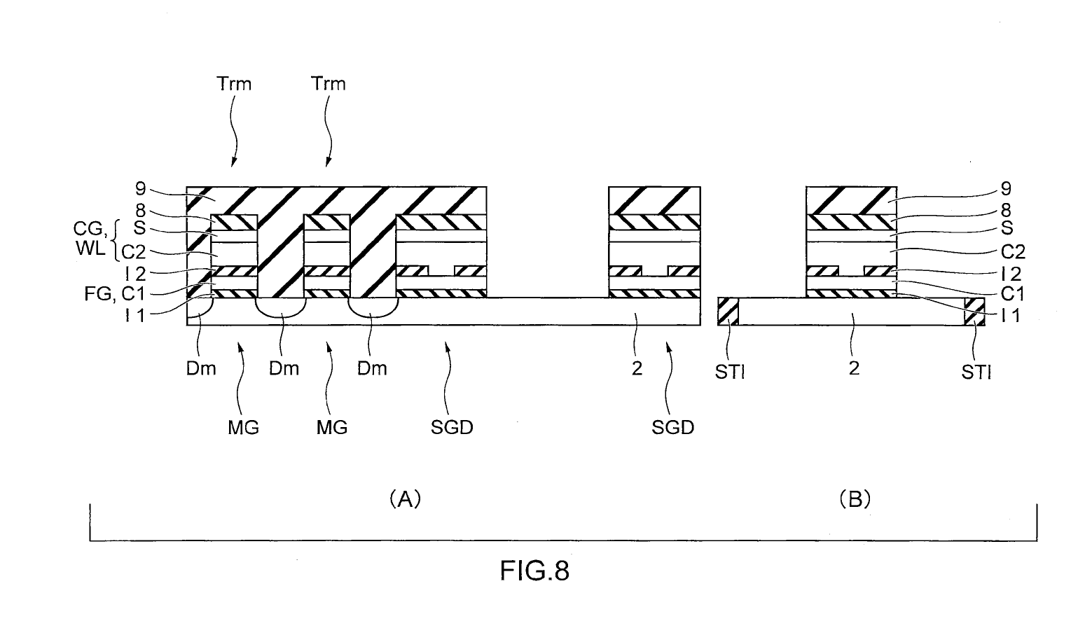

As shown in FIG. 8, using the resist pattern 30 as a mask, anisotropic etching is performed on the silicon nitride film 8, the silicon layer “C2”, the inter-gate insulating film “I2”, the silicon layer “C1”, and the gate insulating film “I1” to form the selecting gate electrode “SGD” of the selecting gate transistor “Trs1” and the gate electrode of the peripheral transistor “Trx”. The resist pattern 30 is then removed (regions (A) and (B) of FIG. 8).

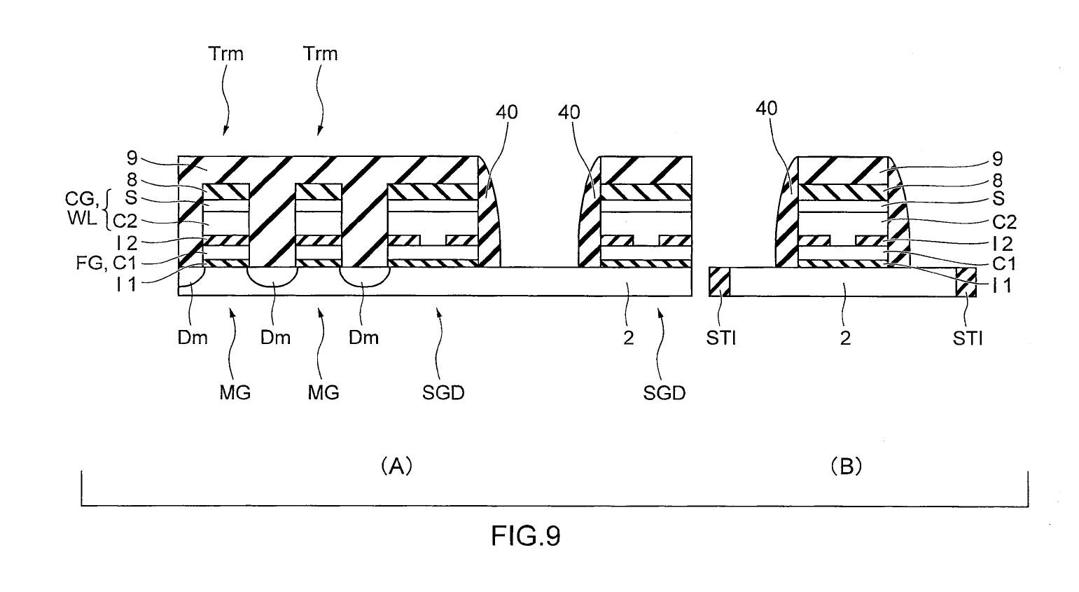

As shown in FIG. 9, the gate side walls 40 of the selecting gate transistor “Trs1” and the peripheral transistor “Trx” are then formed.

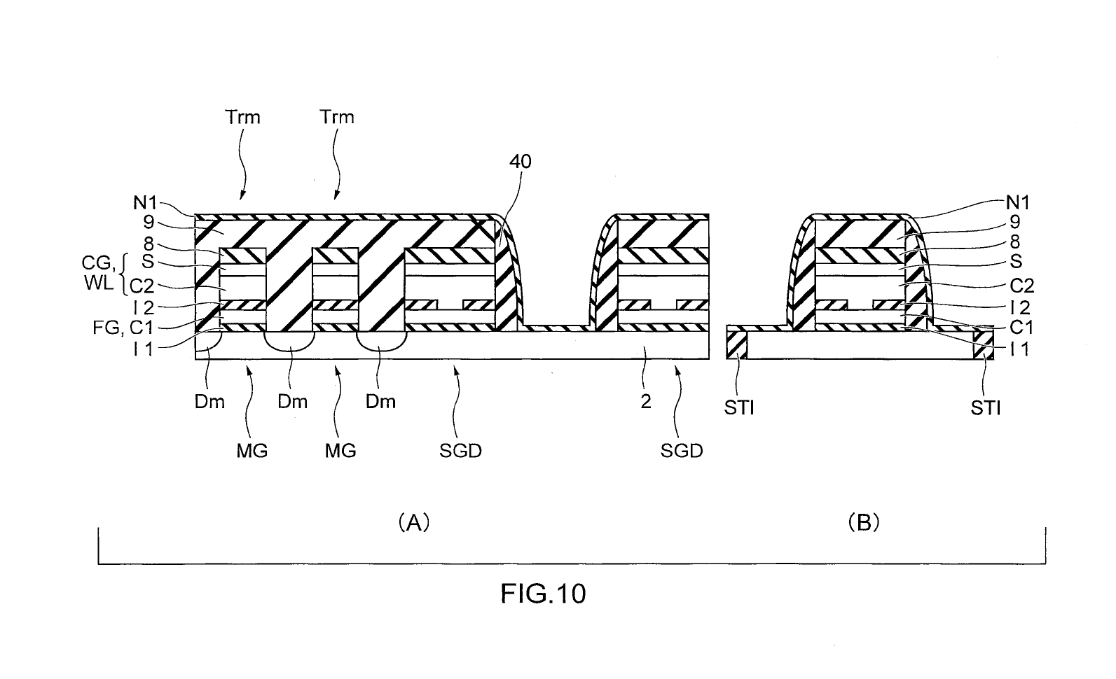

As shown in FIG. 10, the first nitride film “N1” is then formed by CVD, for example, on the interlayer insulating film 9, the gate side walls 40, and the regions in which the source/drain regions of the selecting gate transistor “Trs1” and the peripheral transistor “Trx” are formed.

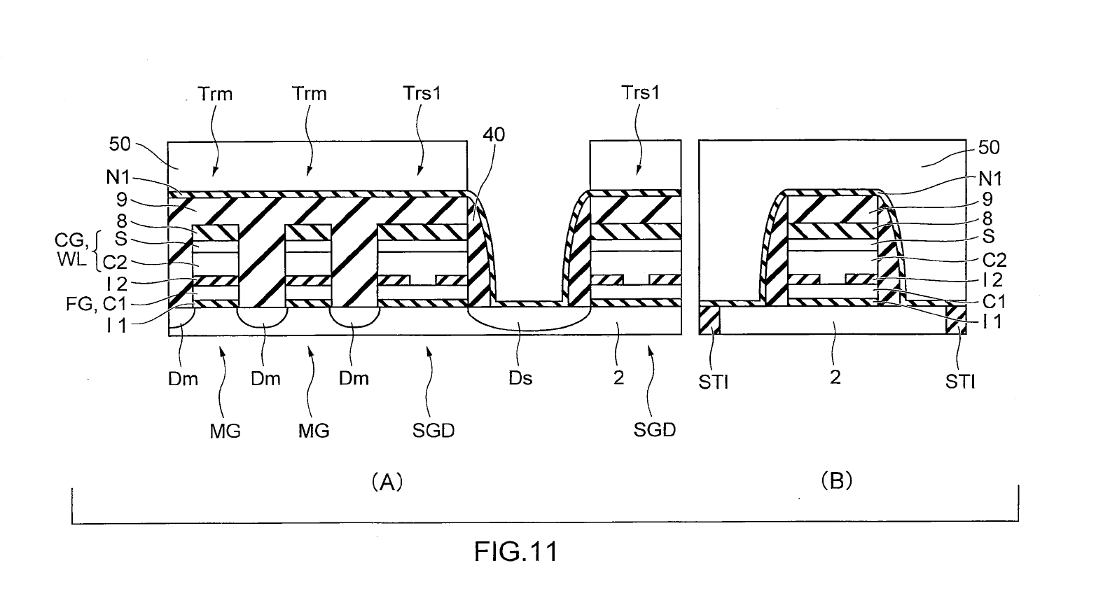

As shown in FIG. 11, using a resist pattern 50 as a mask, an impurity is implanted into the surface layer of the semiconductor substrate 2 by ion implantation. A heat treatment required to activate the impurity is then performed to form a diffusion layer as the source/drain region “Ds” in a self-aligned manner.

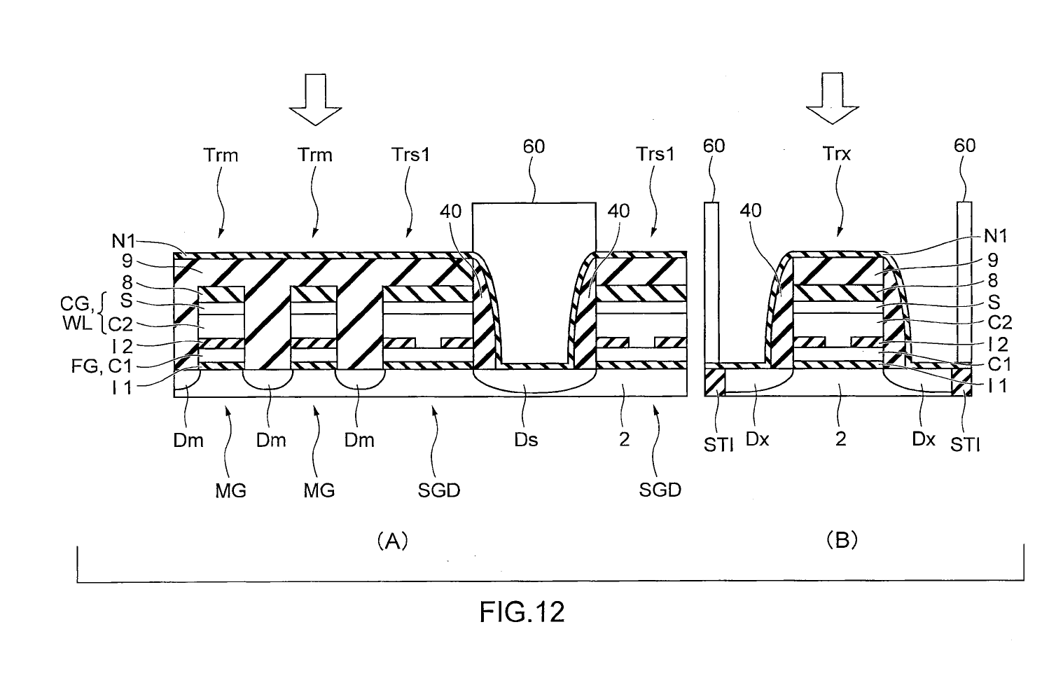

As shown in FIG. 12, the first impurity is then implanted into the first nitride film “N1” by ion implantation using as a mask a resist pattern 60 that has openings at positions over the memory cell region where the memory cell transistor “Trm” is positioned and the region of the peripheral transistor “Trx”, for example. As described above, the first impurity contains any of BF₂, As and P.

The ion implantation into the first nitride film “N1” is performed at the same time as the ion implantation into the source/drain regions of the peripheral transistor “Trx” positioned in the peripheral circuit region on the semiconductor substrate 2. In this case, for example, the first impurity is the same as a second impurity in the source/drain region “Dx” of the peripheral transistor “Trx” positioned in the peripheral circuit region on the semiconductor substrate 2.

The energy of the ion implantation is set so that the first impurity exists in the first nitride film “N1”. More preferably, the energy of the ion implantation is set so that the first impurity exists in the region of the interlayer insulating film 9 directly below the first nitride film “N1” (between the upper part of the multilayer gate electrode “MG” and the lower surface of the first nitride film “N1”). In particular, the energy of the ion implantation is set so that a peak of the concentration distribution of the first impurity lies in the region of the interlayer insulating film 9 directly below the first nitride film “N1”.

As described above, the ion implantation is to selectively implant the first impurity into the first nitride film “N1” in the memory cell region using as a mask the resist that has an opening at a position over the memory cell region in which the memory cell transistor “Trm” is positioned and covers the bit line contact region.

After the ion implantation, the heat treatment (activation annealing) is performed, thereby activating the impurity in the source/drain regions “Dx” of the peripheral transistor “Trx”.

Therefore, as described later, in manufacture of the NAND flash memory (in a heat treatment such as activation annealing), the tunnel insulating film “I1” of the memory cell transistor “Trm” can be prevented from reacting with hydrogen of an ethyl or the like in the interlayer insulating films 9 and 10 or the like. In other words, deterioration of the tunnel insulating film “I1” of the memory cell transistor “Trm” can be prevented.

As shown in FIG. 12, since the ion implantation for forming the source/drain regions “Dx” of the peripheral transistor “Trx” and the ion implantation into the first nitride film “N1” in the memory cell region are performed in the same step, the ion implantation into the first nitride film “N1” in the memory cell region can be performed without increasing the number of steps.

The ion implantation for forming the source/drain regions “Dx” of the peripheral transistor “Trx” and the ion implantation into the first nitride film “N1” in the memory cell region may be performed in different steps.

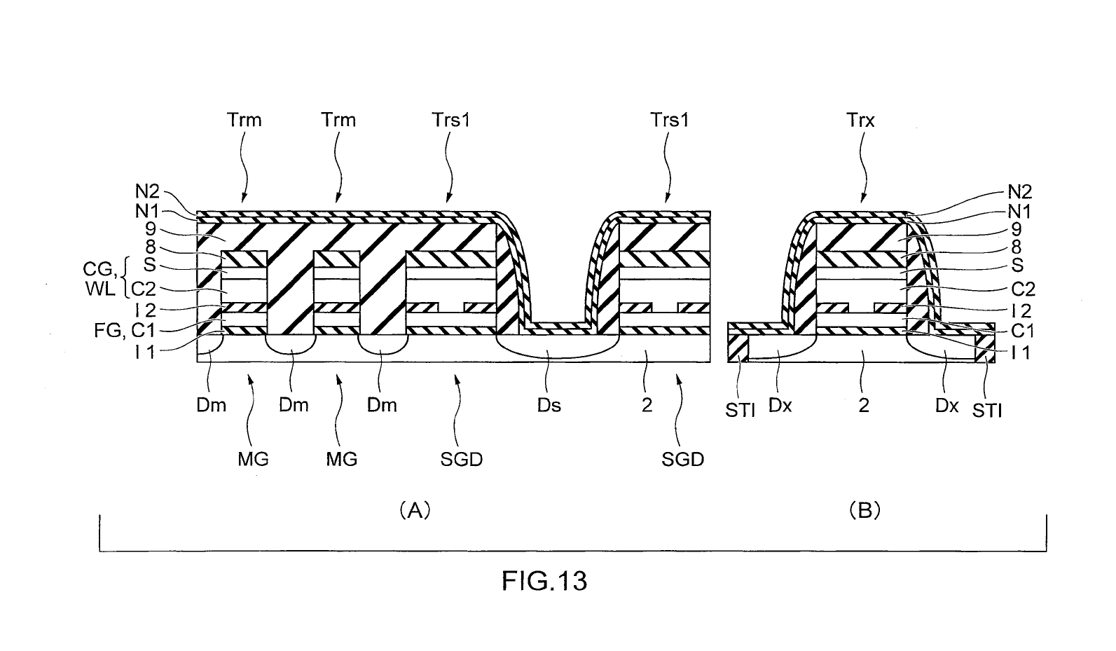

As shown in FIG. 13, after the ion implantation into the first nitride film, the second nitride film “N2” is then formed on the first nitride film “N1” by CVD, for example.

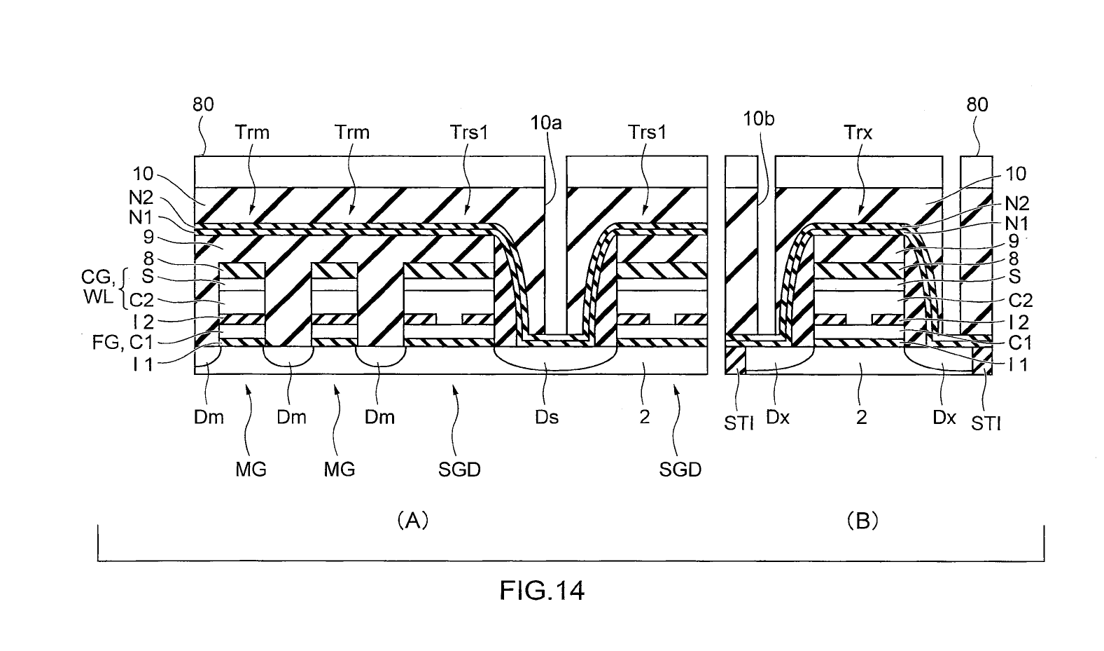

The interlayer insulating film 10 is then formed on the nitride film “N2” on the first nitride film “N1”. As shown in FIG. 14, a resist pattern 80 is formed that is used to form a contact hole in the region where the bit line contact “CB” is to be formed. Using the resist pattern 80 as a mask, contact holes 10a and 10b that penetrate to the first and second nitride films “N1” and “N2” are then formed.

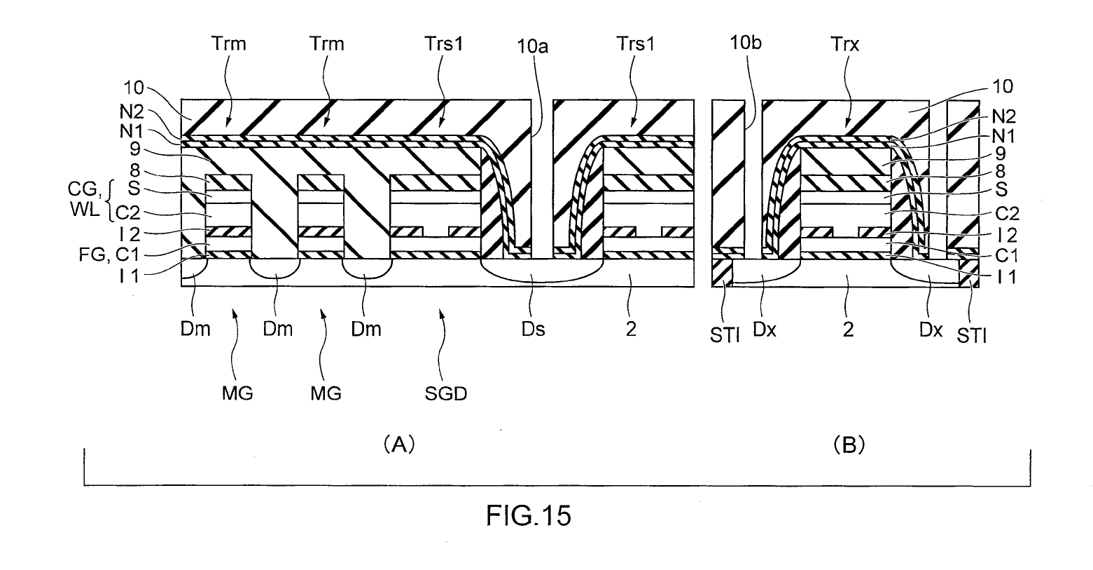

In addition, as shown in FIG. 15, the first and second nitride films “N1” and “N2” are etched to extend the contact holes 10a and 10b to the upper surface of the semiconductor substrate 2.

The bit line contact “CB” and the contact “Cx” are then embedded in the contact holes 10a and 10b. The bit line “BL” and the wire “Lx” to be connected to the bit line contact “CB” and the contact “Cx” are then formed on the interlayer insulating film 10. In this way, the structure of the NAND flash memory 1 shown in FIG. 3 is formed.

Next, an example of characteristics of the NAND flash memory 1 manufactured as described above will be described.

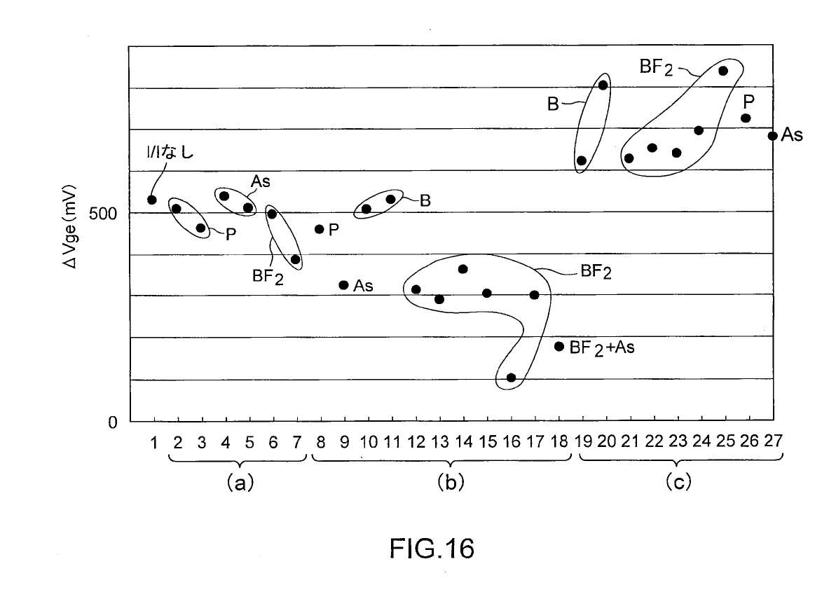

FIG. 16 is a characteristic diagram showing an example of relationships between a voltage change ΔVge of the voltage that is applied to the tunnel oxide film when a constant current is passed through the tunnel oxide film for a prescribed time and various kinds of impurities ion-implanted. In FIGS. 16, (a)2 to (a)7 denote samples into which an impurity is ion-implanted before the first nitride film “N1” is formed, (b)8 to (b)18 denote samples into which an impurity is ion-implanted after the first nitride film “N1” is formed and before the second nitride film “N2” is formed, and (c)19 to (c)27 denote samples into which an impurity is ion-implanted after the first nitride film “N1” is formed and before the second nitride film “N2” is formed.

As shown in FIG. 16, of the samples (a)2 to (a)7, the samples into which BF₂ is ion-implanted have slightly smaller voltage changes ΔVge than a sample into which no impurity is ion-implanted (sample without I/I), and the samples into which another ionic species (P or As) is ion-implanted have approximately the same levels of voltage change ΔVge as the sample into which no impurity is ion-implanted.

The samples (c)19 to (c)27 have substantially greater voltage changes ΔVge than the sample into which no impurity is ion-implanted (sample without I/I).

Of the samples (b)8 to (b)18, the samples into which B is ion-implanted have approximately the same levels of voltage change ΔVge as the sample into which no impurity is ion-implanted (sample without I/I), the sample into which P is ion-implanted has a slightly smaller voltage change ΔVge than the sample into which no impurity is ion-implanted (sample without I/I), and the samples into which As and/or BF₂ is ion-implanted have substantially smaller voltage changes ΔVge than the sample into which no impurity is ion-implanted (sample without I/I).

In particular, for the samples (b)12 to (b)17, the energy of ion implantation ranges from 5 to 20 keV, and the dose ranges from 0.5e15 ions/cm² to 5.0e15 ions/cm². This condition for ion implantation is a condition for the peak of the concentration distribution of BF₂, which is the first impurity, to lie in the region of the interlayer insulating film 9 directly below the first nitride film “N1”.

The energy for the sample (b)16 is 20 keV, and the sample (b)16 has the highest dose of 5.0e15 ions/cm². From this fact, it can be considered that the voltage change ΔVge decreases as the dose increases.

For the samples (b)9 and (b)12 to (b)16 into which As or BF₂ is ion-implanted, the voltage changes ΔVge are reduced, and it can be considered that atoms (molecules) having higher masses are more effective. Besides, BF₂ is considered to effectively expel hydrogen from the interlayer insulating film in ion implantation.

The sample (b)18 into which As and BF₂ are ion-implanted is a sample prepared by ion-implanting As into the sample (b)17 into which only BF₂ is ion-implanted. For the sample (b)18, the voltage change ΔVge is even smaller than that for the sample (b)17.

As described above, it can be considered that the voltage change ΔVge can be reduced by performing ion implantation of BF₂, As or P, preferably BF₂, as the first impurity after the first nitride film “N1” is formed (in particular, and before the second nitride film “N2” is formed).

Thus, as described above, the method of manufacturing the semiconductor storage apparatus according to this embodiment includes ion implantation of the first impurity (BF₂, As or P) into the first nitride film.

In this way, in manufacture of the NAND flash memory 1 (in a heat treatment such as activation annealing), the tunnel insulating film “I1” of the memory cell transistor “Trm” can be prevented from reacting with hydrogen of an ethyl or the like in the interlayer insulating films or the like. In other words, deterioration of the tunnel insulating film “I1” of the memory cell transistor “Trm” can be prevented.

As described above, according to the method of manufacturing the semiconductor storage apparatus according to this embodiment, deterioration of the reliability of the memory cell can be prevented.

The above embodiment has been described by taking a non-volatile NAND flash memory as an example of the semiconductor storage apparatus. However, the present invention can be equally applied to other semiconductor storage apparatuses, such as Bics, NOMOS, ReRAM or DRAM, as far as they have a structure in which an interlayer insulating film (that covers the memory cell) is formed on the memory cell and an upper part of the interlayer insulating film is covered with a nitride film.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of manufacturing a semiconductor storage apparatus, comprising:
forming an array of a plurality of memory cells;
forming an interlayer insulating film that covers the memory cells;
forming a first nitride film that covers an upper part of the interlayer insulating film; and
ion-implanting a first impurity into the first nitride film.

2. The method of manufacturing a semiconductor storage apparatus according to claim 1, wherein the first impurity is any of BF₂, As and P.

3. The method of manufacturing a semiconductor storage apparatus according to claim 1, wherein the first nitride film contains SiN.

4. The method of manufacturing a semiconductor storage apparatus according to claim 1, wherein the memory cells have a multilayer structure including a tunnel insulating film formed on a memory cell region, a charge storing layer formed above the tunnel insulating film, an interlayer insulating film formed on an upper side of the charge storing layer and a control gate electrode formed above the interlayer insulating film, adjacent memory cells share a source region and a drain region, and the array of the plurality of memory cells is formed in the memory cell region.

5. The method of manufacturing a semiconductor storage apparatus according to claim 4, wherein the tunnel insulating film includes a silicon oxide film.

6. The method of manufacturing a semiconductor storage apparatus according to claim 1, wherein the interlayer insulating film includes a silicon oxide film or a tetraethyl orthosilicate (TEOS) film.

7. The method of manufacturing a semiconductor storage apparatus according to claim 1, wherein a second nitride film is formed on the first nitride film after the ion implantation.

8. The method of manufacturing a semiconductor storage apparatus according to claim 1, wherein an energy of the ion implantation is set so that the first impurity exists in the first nitride film.

9. The method of manufacturing a semiconductor storage apparatus according to claim 1, wherein an energy of the ion implantation is set so that the first impurity exists in a region of the interlayer insulating film directly below the first nitride film.

10. The method of manufacturing a semiconductor storage apparatus according to claim 1, wherein an energy of the ion implantation is set so that a peak of a concentration distribution of the first impurity lies in a region of the interlayer insulating film directly below the first nitride film.

11. The method of manufacturing a semiconductor storage apparatus according to claim 1, wherein the ion implantation is performed at the same time as ion implantation into a source region and a drain region of a peripheral transistor disposed in a peripheral circuit region around the memory cells on the semiconductor substrate.

12. The method of manufacturing a semiconductor storage apparatus according to claim 11, wherein an impurity in the source region and the drain region of the peripheral transistor is activated by a heat treatment after the ion implantation.

13. A semiconductor storage apparatus, comprising:
a plurality of memory cells;
an interlayer insulating film formed on the plurality of memory cells; and
a first nitride film that covers an upper part of the interlayer insulating film,
wherein any of BF₂, As and P exists as a first impurity in the first nitride film in a memory cell region.

14. The semiconductor storage apparatus according to claim 13, wherein the memory cells have a multilayer structure including a tunnel insulating film, a charge storing layer formed above the tunnel insulating film, an interlayer insulating film formed on an upper side of the charge storing layer and a control gate electrode formed above the interlayer insulating film, adjacent memory cells share a diffusion layer, and are arrayed.

15. The semiconductor storage apparatus according to claim 14, wherein the first nitride film is a silicon nitride film.

16. The semiconductor storage apparatus according to claim 14, wherein the tunnel insulating film is a silicon nitride film.

17. The semiconductor storage apparatus according to claim 14, wherein the interlayer insulating film includes a silicon oxide film or a tetraethyl orthosilicate (TEOS) film.

18. The semiconductor storage apparatus according to claim 14, wherein the first impurity exists in a region of the interlayer insulating film directly below the first nitride film.

19. The semiconductor storage apparatus according to claim 14, wherein a peak of the concentration distribution of the first impurity lies in a region of the interlayer insulating film directly below the first nitride film.

20. The semiconductor storage apparatus according to claim 14, wherein the first impurity is the same as an impurity in a source region and a drain region of a peripheral transistor disposed in a peripheral circuit region around the memory cells on the semiconductor substrate.
